(19) United States
(12) Patent Application Publication
(10) Pub. No.: US 2002/0181271 A1
(43) Pub. Date: Dec. 5, 2002

(54) Dynamic random access memory cell

(76) Inventor: Jhy-Jyi Sze, Tainan City (TW)

Correspondence Address: POWELL, GOLDSTEIN, FRAZER & MURPHY LLP, P.O. Box 97223, Washington, DC, 20090-7223, US

(21) Appl. No.: 09/865,736

(22) Filed: May 29, 2001

(51) Int. Cl. G11C 11/24

(52) U.S. Cl. 365/149

(57) ABSTRACT

A dynamic random access memory cell, which does not need refresh cycle, comprises following elements: a transistor that gate is coupled to a word line, a capacitor that is coupled to source of the transistor, a switch that is coupled to the source, and a current source that is coupled to the source by the switch. Further, the current source is possible to be provided by a word line which is connected to gate of the transistor, and the switch is possible to be provided by bipolar junction transistor which is located between the capacitor and the current source.

### BACKGROUND OF THE INVENTION

1. Field of the Invention

This invention relates generally to a dynamic random access memory (DRAM) memory cell that does not need refresh cycle, and further relates to a DRAM cell that not only does not need refresh cycle but also does not need extra control signal.

2. Description of the Prior Art

Conventional circuit diagram of DRAM cell at least includes transistor 10 and capacitor 11, where FIG. 1A shows a popular configuration. Moreover, for most of popular cases as FIG. 1B shows, gate 12 of transistor 10 is coupled to word line 13, one doped region 14 of transistor 10 is coupled to sense amplifier 15, and another doped region 16 usually is coupled to capacitor 11. Certainly, actual structure of DRAM cell is variable and there are numerous existent structures.

During operation of DRAM cell, signal, especially high level (high voltage) signal, is stored in the capacitor, and then whether capacitor could properly maintain storaged signal(s) is a key factor about quality of DRAM cell. In fact, leakage current always is unavoidable for available capacitor of semiconductor device, and an direct defect is that stored signal(s) will be lost such that operation of DRAM cell is wrong.

Because that formation of an ideal capacitor without leakage current must overcome meet numerous technological difficulties and pay expensive cost, the popular solution is to periodically perform refresh cycles which supply current to capacitor for compensating lost charges which induced by leakage current. However, because that execution of refresh cycle almost affects normal operation of DRAM cell, such as temporarily suspend normal reading and writing of DRAM cell, operating velocity of DEAM cell (or DRAM cells array) will be degraded by application of refresh cycle.

Accordingly, although refresh cycle is an useful way to compensate lost charges, refresh cycle also induces some disadvantages which is more serious while high operating frequency DRAM is required. Therefore, it is desired to develop a new DRAM cell which can avoid damage of leakage current and damage of refresh cycle at the same time.

### SUMMARY OF THE INVENTION

One main object of the invention is to present a DRAM cell which does not need refresh cycle.

An important object of the invention is to present a DRAM cell which is easy to be produced, especially the differences between the present DRAM cell and other well-known kinds of DRAM cell are not too large to let fabrication of the present DRAM cell is strongly different from fabrication of other well-known kinds of DRAM cell.

Still an essential object of the invention is to present a DRAM cell by limiting circuit diagram of the present DRAM cell but not by limiting structure of the present DRAM cell. In other words, there are various structures of the present DRAM cell.

Further, another main object of the invention is to present a DRAM cell which does not need extra control signal for supplying current to capacitor in time to compensate lost chargers.

One embodiment of the invention is a DRAM cell, comprises following elements: a transistor, a capacitor, a switch and a current source. Whereby, gate of the transistor is coupled to a word line, capacitor is coupled to source of the transistor, switch is coupled to source of the gate, and current source also is coupled to the source by the switch.

Another embodiment of the invention is a DRAM cell, comprises following elements: a transistor, a sub word line, a capacitor and additional doped region. Whereby, transistor comprises a gate, a first doped region and a second doped region; sub word line couples the gate to an inverter, and the inverter couples the sub word line to a main word line; capacitor is coupled to the first doped region; and additional doped region is coupled to main word line. Further, additional doped region is adjacent to first doped region such that a bipolar junction transistor is formed by first doped region, additional doped region and an intermediate substrate between first doped region and additional doped region.

### BRIEF DESCRIPTION OF THE DRAWINGS

A more complete appreciation and many of the attendant advantages thereof will be readily obtained as the same becomes better understood by reference to the following detailed description when considered in connection with the accompanying drawings.

FIG. 1A and FIG. 1B are two sketch maps about circuit diagram of conventional DRAM cell;

FIG. 2A and FIG. 2B are two sketch maps about circuit diagram of one preferred embodiment of the invention;

FIG. 2C shows rules about open or close of switch in previous embodiment;

FIG. 3A shows sketch maps about one possible configuration of the invention; and

FIG. 3B shows rules about open or close of bipolar junction transistor in previous possible configuration.

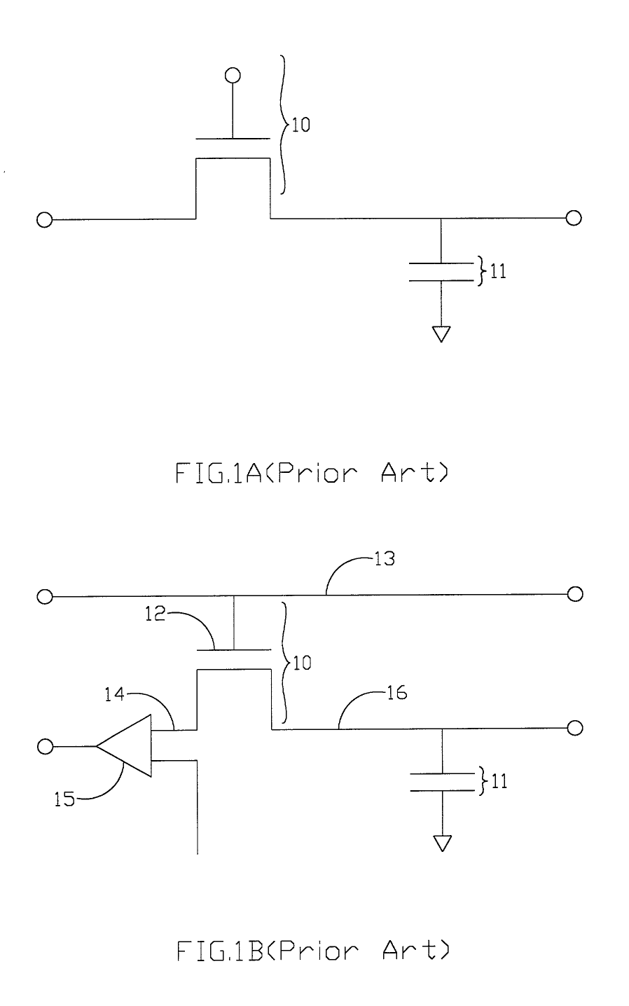

### DESCRIPTION OF THE PREFERRED EMBODIMENT

Because function of refresh cycle is to compensate lost charges of capacitor by supplying current into capacitor. The Applicant incisively points out an important clue: circuit for providing current into capacitor for compensating chargers and circuit for controlling operation of DRAM cell, such as word line and bit line, is possible to be separated. Moreover, the Applicant emphasizes following truth: while circuit for providing current to capacitor and circuit for controlling operation of DRAM cell are separated, operation of both word line and bit line for controlling both reading and writing of DRAM cell will not be necessary to be interrupted for performing the refresh cycle such that current can be supplied to capacitor.

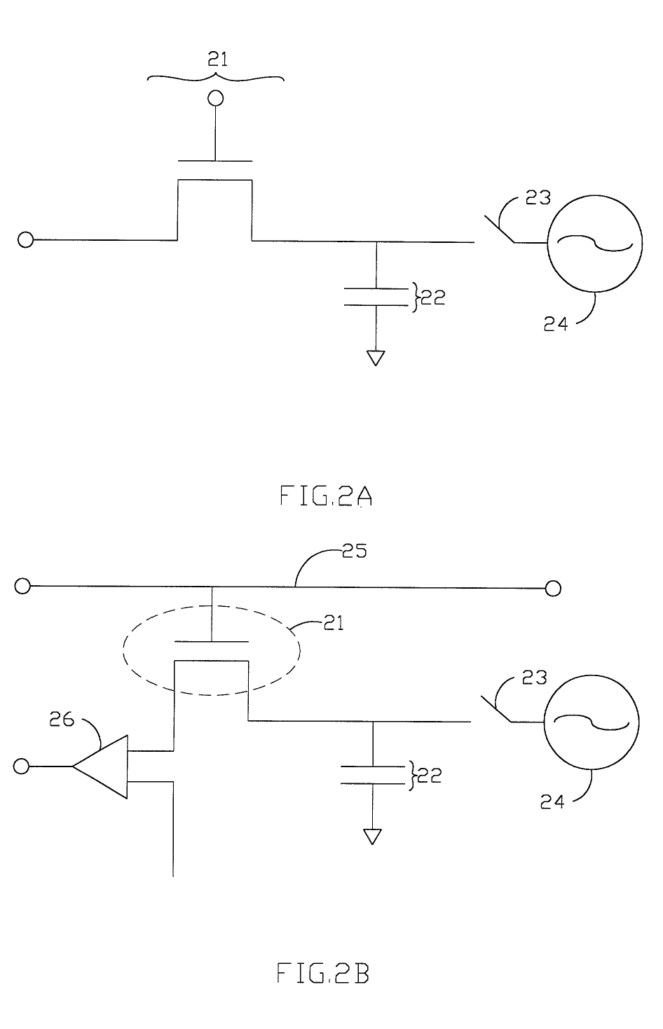

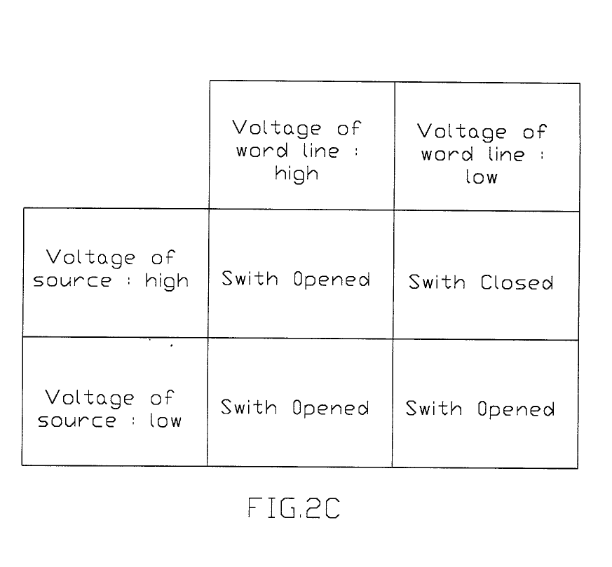

To further explain previous idea, the Applicant provides a preferred embodiment: a dynamic random access memory cell. Refers to FIG. 2A, which is a circuit diagram for the present invention does not focus on actual structure of DRAM cell but really focuses on circuit of DRAM cell, the embodiment at least includes transistor 21, capacitor 22, switch 23 and current source 24.

In detail, as an example shown in FIG. 2B, gate of transistor 21 is coupled to word line 25, capacitor 22 is coupled to source of transistor 21, switch 23 is coupled to source, current source 24 is coupled to the source by switch 23, and drain of transistor 21 usually is coupled to a sense amplifier. Significantly, capacitor 22 is coupled to two circuits simultaneously now: one circuit is provided by transistor 21 and can used to read and write signal, and another circuit is provided by both switch 23 and current source 24 and can be used to supply chargers into capacitor 22. Indisputably, because current source 24 will provide current to capacitor 22 whenever switch 23 is closed, the embodiment does not need to perform any refresh cycle by the circuit which is used to write and read as what well-known arts do. Naturally, all defects induced by refresh cycle are eliminated by the embodiment.

Furthermore, because transistor 21 is conducted while voltage of word line 25 is high, such as 5 voltage which is used by most of semiconductor devices to indicate signal of high, to let channel under gate is established, and also because signal can be write into capacitor 22 or read out capacitor 22 through the channel under gate is established. It is reasonable that switch 23 is opened to prevent normal operation of capacitor 22 is interfered by current from current source 24 while voltage of word line 25 is high. Besides, in order to avoid normal condition of transistor 21 is improperly interfered and to supply lost charge in time, it also is reasonable that switch 23 is opened while voltage of source of transistor 21 is low. A general but not absolute limitation is shown in FIG. 2C.

In short, it is better that switch 23 is closed to let current can flow from current source 24 to capacitor 22 whenever both voltage of word line is low and voltage of source of transistor 21 is high.

For the invention, both available varieties of current source 24 and available varieties of switch 23 are numerous. For example, current source 24 is possible to be provided by some conductive lines which couples with external pads by a multi-level metal structures, switch 23 is possible to be controlled by a controlling circuit which is coupled to both word line(s) and bit line(s) for deciding whether switch 23 should be opened or not. However, in order to simplify structure of this present DRAM cell, it is better to incorporate both current source 24 and switch 23 with both word line(s) and bit line(s). Thus, another embodiment, as discussed below, is present to show a practical and beneficial structure of this invention.

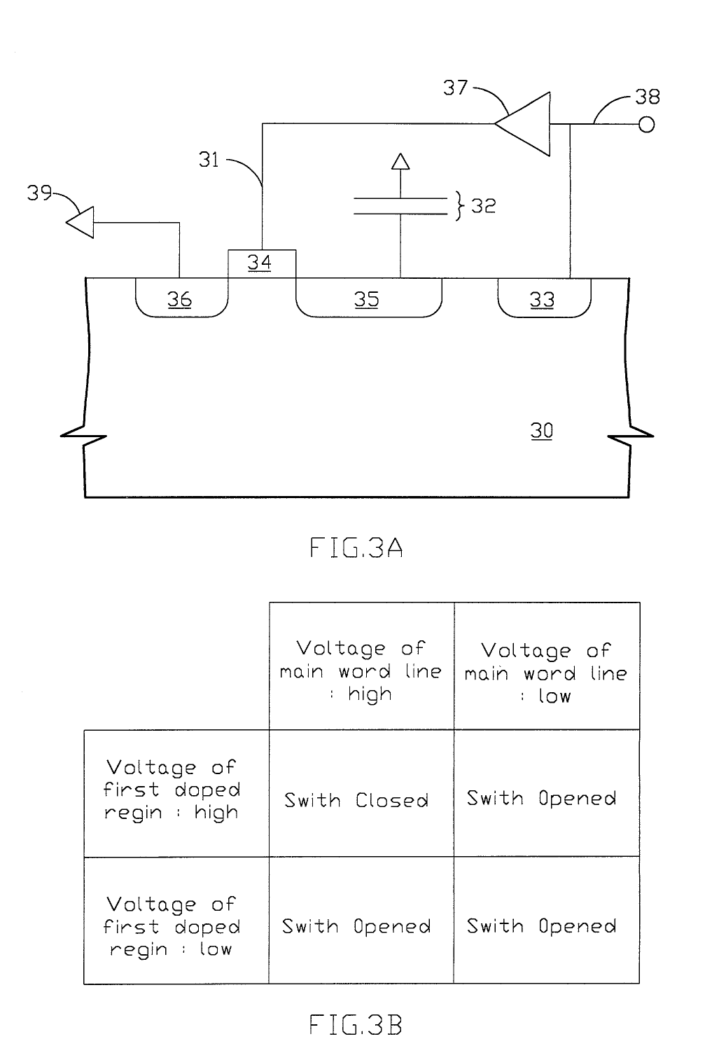

Another embodiment is a dynamic random access memory cell, and focuses on a practical structure. As FIG. 3A shows, this embodiment comprises following elements: transistor which is formed in and on substrate 30, sub word line 31, capacitor 32 and additional doped region 33.

In the present structure, transistor comprises gate 34, first doped region 35 and second doped region 36; sub word line 31 couples gate to inverter 37, and inverter 37 couples sub word line 31 to a main word line 38 which usually connects to several DRAM cells by connecting to several sub word line 31 of several DRAM cell, and capacitor 32 is coupled to first doped region 35. Whereby, voltage of sub word line 31 is opposite to voltage of main word line 37. In additional, second doped region 36 usually is coupled to sense amplifier 39.

Additional doped region 33 is one of main characteristics of this embodiment. Whereby, additional doped region 33 is directly coupled to main word line 38, and is adjacent to first doped region 35 such that a bipolar junction transistor is formed by first doped region 35, additional doped region 33 and an intermediate substrate 30 between first doped region 35 and additional doped region 33. Obviously, main word line 38 is possible to provide current through both additional doped region 33 and first doped region 35 to capacitor 32 whenever bipolar junction transistor is operated at near punchthrough, otherwise, no current is sent to capacitor 32 from main word line 38. In other words, bipolar junction transistor plays the role of switch.

Accordingly, the distance between additional doped region 33 and first doped region 35 should be adjusted to let the depletion region around additional doped region 33 can contact the depletion region around first doped region 35 whenever bipolar junction transistor is operated at near punchthrough. Further, as discussed in the former embodiment, it is better for this bipolar junction transistor to operate at near punchthrough whenever both voltage of main word line 38 is high and voltage of first doped region 35 is high. Further, these two limitation could be generalized as following: it is better for this bipolar junction transistor to does not operate at near punchthrough whenever voltage of main word line 38 is low, it also is better for this bipolar junction transistor to does not operate at near punchthrough whenever voltage of first doped region 35 is low, refers to FIG. 3B.

From the foregoing it will be appreciated that, although specific embodiments of the invention have been described herein for purpose of illustration, various modification may be made without deviating from the spirit and scope of the invention. Accordingly, the invention is not limited except as by the appended claims.

What is claimed is

1. A dynamic random access memory cell, comprising:
a transistor, wherein a gate of said transistor is coupled to a word line;
a capacitor, wherein said capacitor is coupled to a source of said transistor;
a switch, wherein said switch is coupled to said source; and
a current source, wherein said current source is coupled to said source by said switch.

2. The cell of claim 1, wherein a drain of said transistor is coupled to a sense amplifier.

3. The cell of claim 1, wherein said current source provides current to said capacitor whenever said switch is closed.

4. The cell of claim 1, wherein said switch is closed whenever both voltage of said word line is low and voltage of said source is high.

5. The cell of claim 1, wherein said switch is opened whenever voltage of said word line is high.

6. The cell of claim 1, wherein said switch is opened whenever voltage of said source is low.

7. A dynamic random access memory cell, comprising:
a transistor, wherein said transistor comprises a gate, a first doped region and a second doped region;
a sub word line, wherein said sub word line couples said gate to an inverter, and said inverter coupling said sub word line to a main word line;
a capacitor, wherein said capacitor is coupled to said first doped region; and
an additional doped region, wherein said additional doped region is coupled to said main word line, and said additional doped region being adjacent to said first doped region such that a bipolar junction transistor is formed.

8. The cell of claim 7, wherein said second doped region is coupled to a sense amplifier.

9. The cell of claim 7, wherein a distance between said additional doped region and said first doped region is adjusted to let the depletion region around said additional doped region can contact the depletion region around said first doped region whenever said bipolar junction transistor is operated at near punchthrough.

10. The cell of claim 7, wherein said bipolar junction transistor is operated at near punchthrough whenever both voltage of said main word line is high and voltage of said first doped region is high.

11. The cell of claim 7, wherein said bipolar junction transistor is not operated at near punchthrough whenever voltage of said main word line is low.

12. The cell of claim 7, wherein said bipolar junction transistor is not operated at near punchthrough whenever voltage of said first doped region is low.

13. The cell of claim 7, wherein said main word line provides current to said capacitor whenever said bipolar junction transistor is operated at near punchthrough.
